(19) United States
(12) Patent Application Publication
(10) Pub. No.: US 2021/0320204 A1
(43) Pub. Date: Oct. 14, 2021

(54) SEMICONDUCTOR DEVICE AND METHOD FOR PRODUCING SAME

(71) Applicants: TOWER PARTNERS SEMICONDUCTOR CO., LTD., Uozu City (JP); TOWER SEMICONDUCTOR LTD., Migdal Haemek (IL)

(72) Inventors: Masao SHINDO, Toyama (JP); Takayuki YAMADA, Toyama (JP); Yoshinobu MOCHO, Toyama (JP); Toshihiko ICHIKAWA, Toyama (JP); Noriyuki INUISHI, Toyama (JP); Hideo ICHIMURA, Toyama (JP); Norio KOIKE, Toyama (JP); Sharon LEVIN, Migdal Haemek (IL); Hongning YANG, Migdal Haemek (IL); David MISTELE, Migdal Haemek (IL); Daniel SHERMAN, Migdal Haemek (IL)

(73) Assignees: TOWER PARTNERS SEMICONDUCTOR CO., LTD., Uozu City (JP); TOWER SEMICONDUCTOR LTD., Migdal Haemek (IL)

(21) Appl. No.: 17/356,188

(22) Filed: Jun. 23, 2021

Related U.S. Application Data
(63) Continuation of application No. PCT/JP2019/044936, filed on Nov. 15, 2019.

(30) Foreign Application Priority Data
Dec. 26, 2018 (JP) 2018-243675

(51) Int. Cl. H01L 29/78; H01L 29/66; H01L 29/40

(52) U.S. Cl. CPC H01L 29/7816; H01L 29/402; H01L 29/66681

(57) ABSTRACT

The semiconductor device includes: a gate electrode on a semiconductor substrate via a gate insulating film; an offset drain layer in the semiconductor substrate on one side of the gate electrode; a drain layer on the offset drain layer; and a source layer in the semiconductor substrate on another side of the gate electrode. The semiconductor device further includes: a protective film covering the semiconductor substrate; a field plate on the protective film, and having a portion above the offset drain layer; and a field plug connected to the field plate and in the protective film and above the offset drain layer, in such a manner as to avoid reaching the offset drain layer.

### CROSS-REFERENCE TO RELATED APPLICATIONS

This is a continuation of International Application No. PCT/JP2019/44936 filed on Nov. 15, 2019, which claims priority to Japanese Patent Application No. 2018-243675 filed on Dec. 26, 2018. The entire disclosures of these applications are incorporated by reference herein.

### BACKGROUND

It is known to provide a field plate on an insulating film covering a gate electrode, a source layer, a drain layer, and the like in a metal-oxide-semiconductor field-effect transistor (MOSFET) provided in a semiconductor device. The field plate is electrically connected to a source electrode (Japanese Unexamined Patent Publication No. S63-64909) or to a drain electrode (Japanese Unexamined Patent Publication No. H09-135021). It is also known to form a polysilicon layer on the drain layer via a local oxidation of silicon (LOCOS) oxide film to electrically connect the polysilicon layer and the field plate (Japanese Unexamined Patent Publication No. 2005-135950). In the Japanese Unexamined Patent Publication Nos. S63-64909, H09-135021, and 2005-135950, these configurations stabilize electric potential above the drain layer even when the electric potential difference between the gate electrode and the drain layer is large, which improves the reliability of the devices.

### SUMMARY

However, in production of the semiconductors of Japanese Unexamined Patent Publication Nos. S63-64909 and H09-135021, stability of the electric potential above the drain layer is insufficient. Thus, the reliability of the device is unsatisfactory. In the configuration of Japanese Unexamined Patent Publication No. 2005-135950, it is necessary to add a process of heat treatment for LOCOS oxidation. For this reason, an influence on other semiconductor elements formed in parallel cannot be ignored. Further, a current path from the drain side to the source side needs to pass under the LOCOS oxide film, and thus is longer. This causes a decrease in the current capability.

In view of the foregoing problems, the present disclosure describes a semiconductor device and a method for producing the same, which enables a field-effect transistor (FET) to have improved reliability and performance without the process of heat treatment.

A semiconductor device of the present disclosure includes: a gate electrode on a semiconductor substrate via a gate insulating film; an offset drain layer in the semiconductor substrate on one side of the gate electrode, and a drain layer on the offset drain layer; a source layer in the semiconductor substrate on another side of the gate electrode; and a protective film covering the semiconductor substrate. The semiconductor device further includes: a field plate on the protective film, the field plate at least having a portion of above the offset drain layer; and a field plug connected to the field plate and in the protective film and above the offset drain layer, in such a manner as to avoid reaching the offset drain layer.

A method for producing a semiconductor device includes: forming a gate electrode on a semiconductor substrate via a gate insulating film, and an offset drain layer in the semiconductor substrate on one side of the gate electrode; forming a source layer in the semiconductor substrate on another side of the gate electrode and a drain layer on the offset drain layer; and forming a protective film covering the semiconductor substrate including the source layer and the drain layer. The method further includes: forming a field plug in the protective film and above the offset drain layer in such a manner as to avoid reaching the offset drain layer; and forming a field plate on the protective film so as to be connected to the field plug.

The semiconductor device of the present disclosure includes a field plug in the protective film and above the offset drain layer. This stabilizes the electric potential in the vicinity of the offset drain layer. As a result, the reliability of the semiconductor device is improved.

### BRIEF DESCRIPTION OF THE DRAWINGS

FIG. 1 illustrates an exemplary semiconductor device of a first embodiment of the present disclosure.

FIG. 2 illustrates an exemplary semiconductor device of a second embodiment of the present disclosure.

FIG. 3 illustrates an exemplary semiconductor device of a third embodiment of the present disclosure.

FIG. 4 illustrates an exemplary semiconductor device of a fourth embodiment of the present disclosure.

FIG. 5 illustrates a process of a method for producing the semiconductor device of the present disclosure.

FIG. 6 illustrates a process of the method for producing the semiconductor device, following the process of FIG. 5.

FIG. 7 illustrates a process of the method for producing the semiconductor device, following the process of FIG. 6.

FIG. 8 illustrates a process of the method for producing the semiconductor device, following the process of FIG. 7.

FIG. 9 illustrates a process of the method for producing the semiconductor device, following the process of FIG. 8.

FIG. 10 illustrates a process of the method for producing the semiconductor device, following the process of FIG. 9.

FIG. 11 illustrates a process of the method for producing the semiconductor device, following the process of FIG. 10.

FIG. 12 illustrates a process of the method for producing the semiconductor device, following the process of FIG. 11.

FIG. 13 is a graph illustrating advantages of the semiconductor device of the present disclosure.

FIG. 14 is a graph illustrating advantages of the semiconductor device of the present disclosure.

### DETAILED DESCRIPTION

Embodiments of the present disclosure will be described below with reference to the drawings.

### First Embodiment

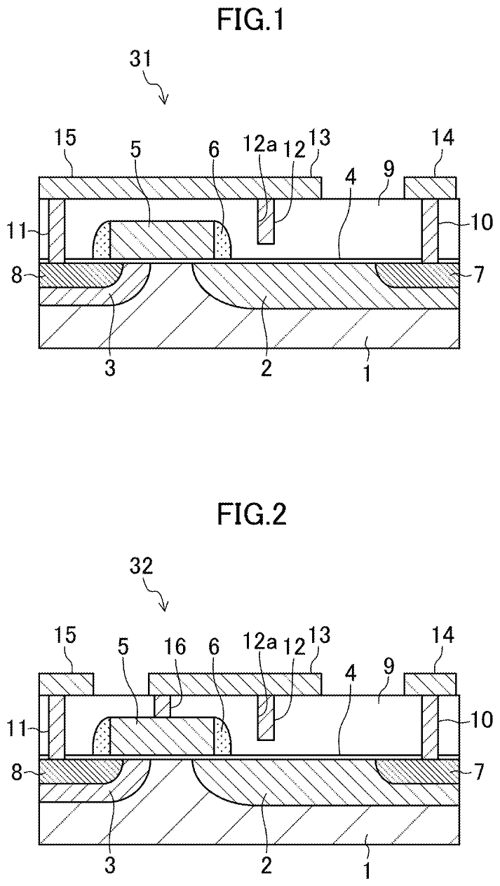

FIG. 1 schematically illustrates an exemplary semiconductor device 31 of a first embodiment of the present disclosure. The semiconductor device 31 is formed using a semiconductor substrate 1 having a p-type semiconductor layer. A gate electrode 5 is provided on the semiconductor substrate 1 via a gate insulating film 4. A p-type body layer 3 having an impurity concentration higher than that of the semiconductor substrate 1, and an n-type source layer 8 provided on the body layer 3 are placed in the semiconductor substrate 1 on one side of the gate electrode. An n-type offset drain layer 2 and an n-type drain layer 7 provided on the offset drain layer 2 and having an impurity concentration higher than that of the offset drain layer 2 are placed in the semiconductor substrate 1 on another side of the gate electrode 5.

A side wall 6 made of, for example, silicon nitride is formed to cover a sidewall of the gate electrode 5. Further, a protective film 9 made of, for example, silicon oxide is provided on the semiconductor substrate 1 to cover the gate electrode 5, the source layer 8, the drain layer 7, and the like.

The protective film 9 is provided with a source hole reaching the source layer 8, and a source contact plug 11, for example, provided by embedding a conductive material that is tungsten in the source hole. Likewise, the protective film 9 is provided with a drain hole reaching the drain layer 7, and a drain contact plug 10 provided by embedding, for example, tungsten in the drain hole.

A source electrode 15 connected to the source contact plug 11 is provided on the protective film 9. A field plate 13 is provided on the protective film 9 and above the offset drain layer 2. The field plate 13 is connected to the source electrode 15. Further, a drain electrode 14 connected to the drain contact plug 10 is provided on the protective film 9.

A field hole 12a is provided in the protective film 9 and above the offset drain layer 2. The field hole 12a extends to the vicinity of the offset drain layer 2, but is formed in such a manner as to avoid reaching the offset drain layer 2. A field plug 12 is formed in the protective film 9 by embedding a conductive material such as tungsten in the field hole 12a.

The field plug 12 is connected to the field plate 13. Therefore, the field plug 12 is electrically connected to the source layer 8 via the field plate 13, the source electrode 15, and the source contact plug 11.

In the semiconductor device 31 such as described above, the field plug 12 is electrically connected to the source layer 8. This maintains the field plug 12 at the same electric potential as that of the source layer 8. The electric potential of the field plug 12 extending to the vicinity of the offset drain layer 2 is fixed. This stabilizes the electric potential above the offset drain layer 2, and improves the reliability of the semiconductor device 31.

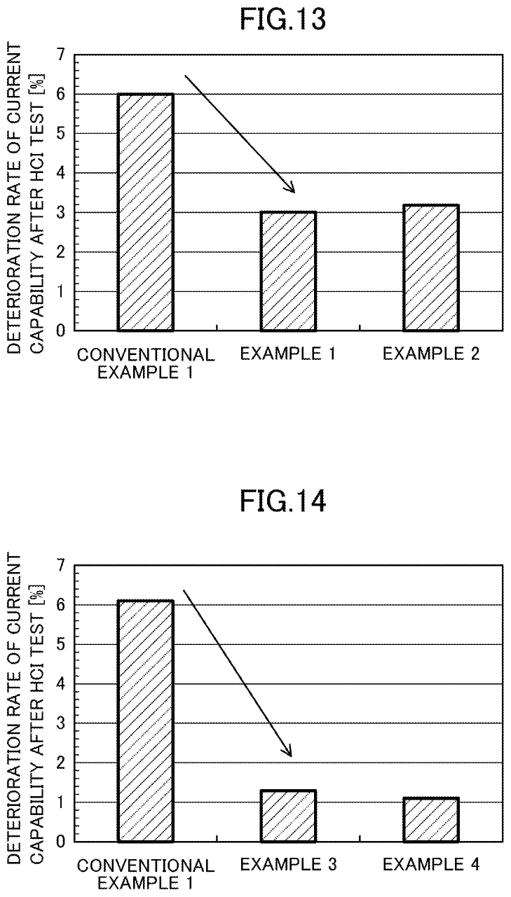

FIG. 13 shows a specific example of an advantage. In general, when a hot carrier injection (HCI) test is performed on a semiconductor device, current capability deteriorates. This is because electrons and holes in a high energy state generated during the HCI test break a bond (dangling bond) at an interface between silicon and an oxide film, thereby generating a trap. The electrons and holes are easily captured in the generated trap, thereby making a charged state. This destabilizes the electric potential inside the semiconductor device, which changes its characteristic.

The semiconductor device of Conventional Example 1 shown in FIG. 13 has the same configuration as the semiconductor device 31 of FIG. 1 except that it includes no field plug 12. In Conventional Example 1, the deterioration rate of the current capability after the HCI test was about 6%. In contrast, in the semiconductor device 31 of the present embodiment (Example 1), the deterioration rate was about 3%. That is, the degree of deterioration was substantially reduced by half. This is considered to be an advantage of providing the field plug 12 to stabilize the electric potential above the offset drain layer 2.

### Second Embodiment

Next, a second embodiment of the present disclosure will be described. FIG. 2 illustrates an exemplary semiconductor device 32 of the present embodiment. The semiconductor device 32 has a configuration similar to that of the semiconductor device 31 of the first embodiment shown in FIG. 1. Thus, in FIG. 2, the same components to those in FIG. 1 are denoted by the same reference numerals. Now, the differences will be mainly described below.

In the semiconductor device 31 of FIG. 1, the field plate 13 is connected to the source electrode 15. In contrast, in the semiconductor device 32 of FIG. 2, the field plate 13 is not connected to the source electrode 15. A gate contact plug 16 is formed by embedding, for example, tungsten in a gate hole provided in the protective film 9 to reach the gate electrode 5. The gate contact plug 16 is connected to the field plate 13. Therefore, the field plug 12 provided above the offset drain layer 2 is electrically connected to the gate electrode 5 via the field plate 13 and the gate contact plug 16.

In the semiconductor device 32 such as described above, the field plug 12 is electrically connected to the gate electrode 5. This maintains the field plug 12 at the same electric potential as that of the gate electrode 5. The electric potential of the field plug 12 extending to the vicinity of the offset drain layer 2 is fixed. This stabilizes the electric potential above the offset drain layer 2, and improves the reliability of the semiconductor device 32.

FIG. 13 shows a specific example of an advantage. In Conventional Example 1, the deterioration rate of the current capability after the HCI test was about 6%, whereas in the semiconductor device 32 of the present embodiment (Example 2), the deterioration rate was about 3.2%. That is, also in the present embodiment, the degree of deterioration was substantially reduced by half

### Third Embodiment

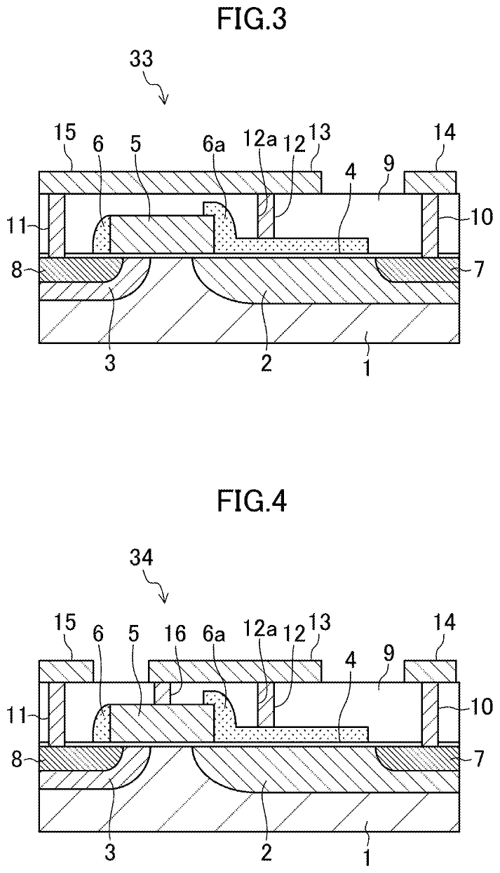

Next, a third embodiment of the present disclosure will be described. FIG. 3 schematically illustrates an exemplary semiconductor device 33 of the present embodiment. The semiconductor device 33 includes a configuration similar to that of the semiconductor device 31 of the first embodiment shown in FIG. 1. Thus, in FIG. 3, the same components to those in FIG. 1 are denoted by the same reference numerals. Now, the differences will be mainly described below.

In the semiconductor device 31 of FIG. 1, the field hole 12a is formed in the protective film 9 in such a manner as to avoid reaching the offset drain layer 2. The field plug 12 is formed by embedding, for example, copper in the field hole 12a. Then, in order for the field hole 12a to avoid reaching the offset drain layer 2, an operation such as finishing the etching is performed at a stage where the protective film 9 sufficiently remains below the field hole 12a.

On the other hand, in the semiconductor device 33 of FIG. 3, an extended side wall 6a covering the offset drain layer 2 is formed, and a field hole 12a is formed in the protective film 9 so as to reach the extended side wall 6a. For example, copper is embedded in the field hole 12a to form the field plug 12.

The extended side wall 6a is formed by extending the side wall 6 covering the sidewall of the gate electrode 5 closer to the drain layer to a portion above the offset drain layer 2. If the protective film 9 is made of, for example, a silicon oxide film, the side wall 6 (extended side wall 6a) is made of a different material, for example, a silicon nitride film. With this configuration, it is possible to make the etching rates of the protective film 9 and the extended side wall 6a differ significantly when etching is performed by a predetermined method.

Thus, when the field hole 12a is formed by etching the protective film 9, the extended side wall 6a functions as an etching stop layer. This allows the field hole 12a to reliably avoid reaching the offset drain layer 2. Accordingly, the field plug 12 formed in the field hole 12a is allowed to further reliably avoid contacting with the offset drain layer 2 and causing a short circuit. Further, the lower surface of the field plug 12 is allowed to be closer to the top surface of the offset drain layer 2 as compared with the semiconductor device 31 of FIG. 1. For example, in the present embodiment, the thickness of the extended side wall 6a on the offset drain layer 2 is approximately 60 nm, and the thickness of the gate insulating film 4 is approximately 10 nm. The distance between a field plug 12 and an offset drain layer 2 is a sum of these two dimensions and adds up to approximately 70 nm. On the other hand, in the first embodiment, the distance between the field plug 12 and the offset drain region 2 is approximately 150 nm.

As described above, the advantage of stabilizing the electric potential above the offset drain layer 2 is further reliably and easily implemented, as compared with the semiconductor device 31 of FIG. 1.

FIG. 14 shows a specific example of the advantage. The semiconductor device of Conventional Example 1 shown in FIG. 14 has the same configuration as the semiconductor device 31 of FIG. 1 except that it includes no field plug 12. In Conventional Example 1, the deterioration rate of the current capability after the HCI test was about 6.1%, whereas in the semiconductor device 33 of the present embodiment (Example 3), the deterioration rate was about 1.3%. That is, the degree of deterioration was reduced to nearly one fifth. In the semiconductor device 31 of the first embodiment (Example 1 in FIG. 13), the deterioration rate was about 3%. Thus, the deterioration was remarkably reduced even in comparison to Example 1. It is considered to be a result of bringing the field plug 12 closer to the offset drain layer 2 as compared to the first embodiment by providing the extended side wall 6a.

### Fourth Embodiment

Next, a fourth embodiment of the present disclosure will be described. FIG. 4 illustrates an exemplary semiconductor device 34 of the present embodiment. The semiconductor device 34 includes a configuration similar to that of the semiconductor device 32 of the second embodiment shown in FIG. 2. Thus, in FIG. 4, the same components to those in FIG. 2 are denoted by the same reference numerals. Now, the differences will be mainly described below.

In the semiconductor device 34 of FIG. 4, just like in the semiconductor device 32 of FIG. 2, the field plate 13 is electrically connected to the gate electrode 5, and the field plug 12 is formed so as to reach the extended side wall 6a.

In such a configuration, just like in the semiconductor device 32 of FIG. 2, the electric potential of the field plug 12 is fixed to the electric potential of the gate electrode 5. Thus, the electric potential above the offset drain layer 2 is stabilized, and the reliability of the semiconductor device 34 is improved. Further, just like in the semiconductor device 33 of FIG. 3, the field plug 12 is allowed to be closer to the top surface of the offset drain layer 2 by using the extended side wall 6a.

FIG. 14 shows a specific example of the advantage. In Conventional Example 1, the deterioration rate of the current capability after the HCI test was about 6.1%, whereas in the semiconductor device 34 of the present embodiment (Example 4), the deterioration rate was about 1.1%. That is, the degree of deterioration was reduced to one fifth or less. In the second embodiment (Example 2 of FIG. 13), the deterioration rate was about 3.1%. Thus, the deterioration was remarkably reduced even in comparison to Example 2. It is considered to be a result of bringing the field plug 12 closer to the offset drain layer 2 as compared to the first embodiment by providing the extended side wall 6a.

(Method for Producing Semiconductor Device)

Next, a method for producing a semiconductor device of the present disclosure will be described, using the semiconductor device 33 of the third embodiment shown in FIG. 3 as an example.

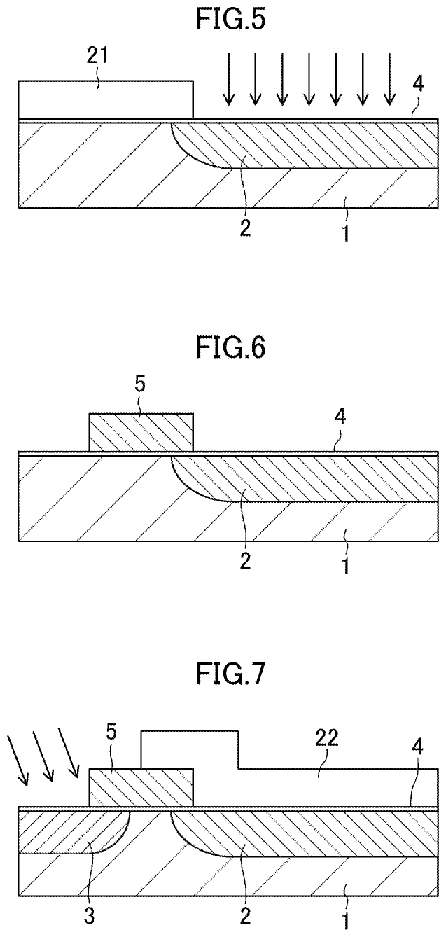

First, a process shown in FIG. 5 will be described. In this process, the semiconductor substrate 1 having a p-type semiconductor layer is prepared. On the surface of the semiconductor substrate 1, a gate insulating film 4 is formed as, for example, a silicon oxide film. Further, a photoresist 21 having a predetermined pattern is formed on the gate insulating film 4. For this purpose, processes such as resist application, exposure to light, and development are performed.

Further, using the formed photoresist 21 as a mask, an n-type impurity such as arsenic (As) or phosphorus (P) is introduced into the semiconductor substrate 1 by ion implantation. In this way, the offset drain layer 2 is formed. The conditions of the implantation may be as follows: phosphorus (P) is used as the implantation ion, the implantation energy is set between 20 keV and 250 keV, the dose amount is set between 1×10¹²/cm² and 5×10¹²/cm², and the implantation angle is set to 7° (the angle formed with respect to a normal line of the primary surface of the semiconductor substrate 1). Thus, the offset drain layer 2 contains an impurity at a concentration of approximately 1×10¹⁷/cm³ to 4×10¹⁷/cm³.

Thereafter, the photoresist 21 is removed with a commonly used technique.

Next, a process shown in FIG. 6 will be described. In this process, the gate electrode 5 is formed. For this purpose, a gate material layer made of the material (e.g., polysilicon) of the gate electrode 5 is formed on the gate insulating film 4. Thereafter, a photoresist (not shown) corresponding to the pattern of the gate electrode 5 is formed on the gate material layer. The gate material layer is patterned by etching to form the gate electrode 5. As shown in FIG. 6, the gate electrode 5 is disposed to overlap with a part of the end portion of the offset drain layer 2.

Next, a process shown in FIG. 7 will be described. In this process, the p-type body layer 3 is formed. For this purpose, a photoresist 22 is formed over the offset drain layer 2 and a part of the gate electrode 5. Next, for example, boron (B) is introduced into the semiconductor substrate 1 as a p-type impurity on the side opposite to the offset drain layer 2 with respect to the gate electrode 5, using the photoresist 22 and the gate electrode 5 as a mask. The conditions of the ion implantation for this purpose may be as follows: boron (B) is used as the implantation ion, the implantation energy is set between 20 keV to 200 keV, and the dose amount is set between 1×10¹²/cm² and 2×10¹³/cm². The implantation angle is set to, for example, 25° such that the body layer 3 extends also below the gate electrode 5. Thus, the offset drain layer 2 contains an impurity at a concentration of approximately 2×10¹⁷/cm³ to 5×10¹⁷/cm³.

Thereafter, the photoresist 22 is removed.

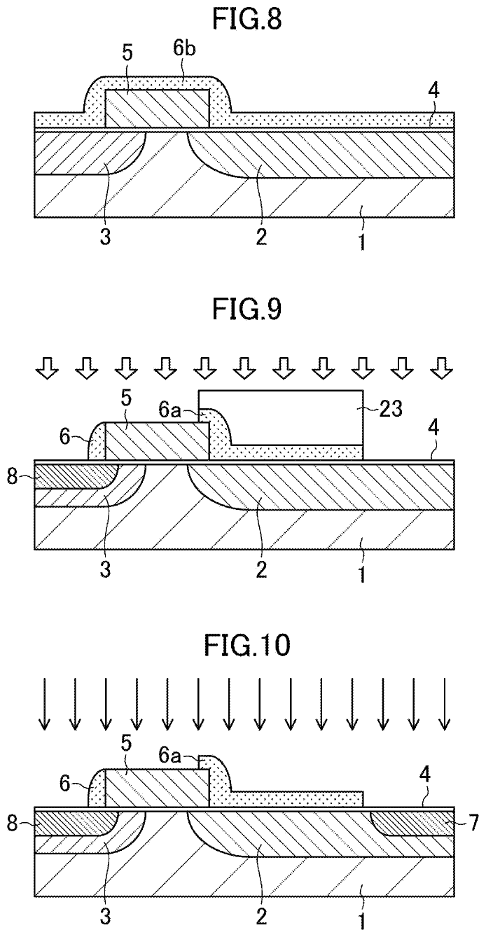

Next, a process shown in FIG. 8 will be described. In this process, a material film 6b such as a silicon nitride film is formed to cover the offset drain layer 2, the body layer 3, and the gate electrode 5. This may be performed by, for example, a chemical vapor deposition (CVD) method. The material film 6b is formed such that the thickness of a portion of the material film 6b on the offset drain layer 2 is approximately 40 nm to 80 nm.

Next, a process shown in FIG. 9 will be described. In this process, the material film 6b is patterned to form the side wall 6 covering the sidewall of the gate electrode 5 closer to the body layer 3, and the extended side wall 6a covering the sidewall of the gate electrode 5 closer to the offset drain layer 2 and a predetermined region above the offset drain layer 2.

For this purpose, first, a photoresist 23 is formed on a region of the material film 6b shown in FIG. 8 where the extended side wall 6a is to be formed. Subsequently, portions of the material film 6b which are not covered with the photoresist 23 are removed by anisotropic etching or the like. When portions of the material film 6b covering the top surface of the gate electrode 5, the body layer 3, and the offset drain layer 2 are removed by using anisotropic etching, the side wall 6 remains on the sidewall of the gate electrode 5 closer to the body layer 3. Thereafter, the photoresist 23 is removed to form the extended side wall 6a.

Next, a process shown in FIG. 10 will be described. In this process, an n-type impurity is ion-implanted into the front surface of the semiconductor substrate 1. As a result, the drain layer 7 is formed in a portion of the offset drain layer 2 which is not covered with the extended side wall 6a, and the source layer 8 is formed on the body layer 3. At this time, the conditions of the ion implantation may be as follows: arsenic (As) is used as the implantation ion, the implantation energy is set to 40 keV, the dose amount is set to 5×10¹⁵/cm², and the implantation angle is set to 0°. Thus, the source layer 8 and the drain layer 7 contain an impurity at a concentration of approximately 5×10²¹/cm³.

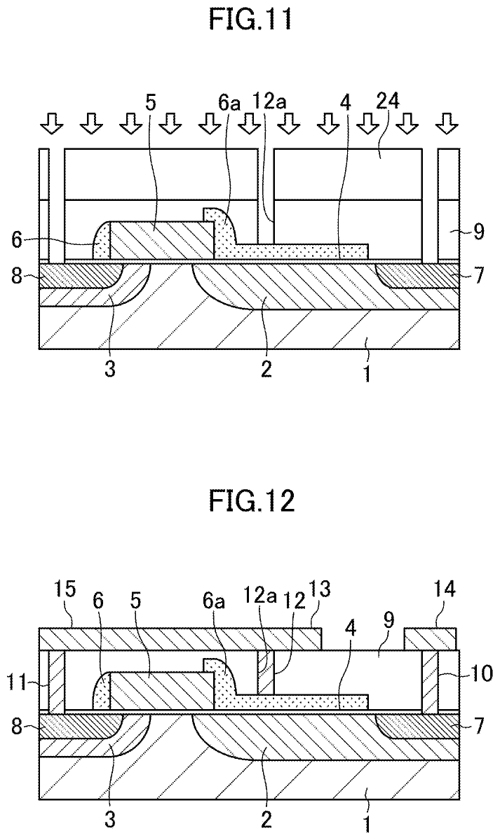

Next, a process shown in FIG. 11 will be described. In this process, the protective film 9 covering the semiconductor substrate 1 is formed. Subsequently, a photoresist 24 is formed on the protective film 9. The photoresist 24 has a pattern with openings at the positions of the field plug 12, the source contact plug 11, and the drain contact plug 10. Further, the protective film 9 is etched using the photoresist 24 as a mask to form the field hole 12a for the field plug 12, the source hole for the source contact plug 11, and a drain hole for the drain contact plug 10. Thereafter, the photoresist 24 is removed.

Next, a process shown in FIG. 12 will be described. In this process, a material such as tungsten is embedded in the holes formed in the process shown in FIG. 11 (the field hole 12a, the source hole, and the drain hole) to form the field plug 12, the source contact plug 11, and the drain contact plug 10. Further, copper or the like is patterned on the protective film 9 to form the source electrode 15, the field plate 13, and the drain electrode 14.

In this way, the semiconductor device 33 of FIG. 3 is produced. This method allows a reduction in additional processes to the known production processes of a semiconductor device including no field plug 12. That is, the field hole 12a is allowed to be formed in parallel with the formation of the source hole and the rain hole. The field hole 12 is further allowed to be formed in parallel with the embedding of tungsten or the like in the holes for the source contact plug 11 and the drain contact plug 10. Therefore, an increase in production costs or the like can be suppressed.

The semiconductor devices of the first, second, and fourth embodiments may be produced by changing some of the above-described processes.

For example, in order to form the semiconductor device 34 of FIG. 4, in the process shown in FIG. 11, a gate hole is provided on the gate electrode 5, and in the process shown in FIG. 12, tungsten or the like is embedded in the gate hole to form the gate contact plug 16. Further, the patterns of the source electrode 15, the field plate 13, and the drain electrode 14 are changed. Thus, the semiconductor device 34 can be produced.

In order to form the semiconductor devices 31 and 32 of FIGS. 1 and 2, the field hole 12a that does not reach the offset drain layer 2 is formed in the protective film 9. This is achieved by setting the processing time of etching or the like.

The numerical ranges, materials, conductivity types, and the like disclosed herein are merely examples, and the present disclosure is not limited thereto.

The technique of the present disclosure is useful as a semiconductor device with improved reliability and a method for producing the same

What is claimed is:

1. A semiconductor device comprising:
a gate electrode on a semiconductor substrate via a gate insulating film;
an offset drain layer in the semiconductor substrate on one side of the gate electrode, and a drain layer on the offset drain layer;
a source layer in the semiconductor substrate on another side of the gate electrode;
a protective film covering the semiconductor substrate;
a field plate on the protective film, the field plate at least having a portion above the offset drain layer; and
a field plug connected to the field plate and in the protective film and above the offset drain layer, in such a manner as to avoid reaching the offset drain layer.

2. The semiconductor device of claim 1, wherein
the field plug is electrically connected to the source layer or the gate electrode.

3. The semiconductor device of claim 1, further comprising:
an extended side wall covering continuously a part of the offset drain layer and a sidewall of the gate electrode closer to the drain layer, and made of a material different from that of the protective film, wherein
the field plug is provided is such a manner as to reach the extended side wall from a top surface of the protective film.

4. A method for producing a semiconductor device, comprising:
forming a gate electrode on a semiconductor substrate via a gate insulating film, and an offset drain layer in the semiconductor substrate on one side of the gate electrode;
forming a source layer in the semiconductor substrate on another side of the gate electrode and a drain layer on the offset drain layer;
forming a protective film covering the semiconductor substrate including the source layer and the drain layer;
forming a field plug in the protective film and above the offset drain layer in such a manner as to avoid reaching the offset drain layer; and
forming a field plate on the protective film so as to be connected to the field plug.

5. The method of claim 4, further comprising:
forming a source contact plug in the protective film reaching the source layer; and
forming a source electrode on the protective film connected to the source contact plug, wherein
the field plate is formed to be connected to the source electrode.

6. The method of claim 4, further comprising:
forming a gate contact plug in the protective film reaching the gate electrode, wherein
the field plate is formed to be connected to the gate contact plug.

7. The method of any one of claim 4, further comprising:
forming an extended side wall covering continuously a part of the offset drain layer and a sidewall of the gate electrode closer to the drain layer, before the forming the source layer and the drain layer, the extended side wall being made of a material different from the protective film, wherein
the field plug is provided to reach the extended side wall of the protective film.
